(19) United States
(12) Patent Application Publication
(10) Pub. No.: US 2008/0261410 A1
(43) Pub. Date: Oct. 23, 2008

(54) METHOD FOR TREATING BASE OXIDE TO IMPROVE HIGH-K MATERIAL DEPOSITION

(75) Inventors: Ming-Ho Yang, Hsinchu County (TW); Liang-Gei Yao, Shin Chu (TW); Shih-Chang Chen, Hsin-Chu (TW)

Correspondence Address: THOMAS, KAYDEN, HORSTEMEYER & RISLEY LLP, 600 GALLERIA PARKWAY, 15TH FLOOR, ATLANTA, GA, 30339, US

(73) Assignee: TAIWAN SEMICONDUCTOR MANUFACTURING CO., LTD., Hsin-Chu (TW)

(21) Appl. No.: 12/145,621

(22) Filed: Jun. 25, 2008

Related U.S. Application Data
(62) Division of application No. 11/048,487, filed on Jan. 31, 2005.

(30) Foreign Application Priority Data
Oct. 29, 2004 (TW) 93133087

(51) Int. Cl. H01L 21/28; H01L 21/306

(52) U.S. Cl. 438/761; 134/3; 257/E21.192; 257/E21.228

(57) ABSTRACT

A method for forming a high-K material layer in a semiconductor device fabrication process including providing a silicon semiconductor substrate or thermally growing interfacial oxide layer comprising silicon dioxide over the silicon substrate; treating with an aqueous base solution or nitridation and depositing a high-K material layer.

### CROSS REFERENCE TO RELATED APPLICATIONS

This application is a division of pending U.S. patent application Ser. No. 11/048,487, filed Jan. 31, 2005 and entitled “METHOD FOR TREATING BASE OXIDE TO IMPROVE HIGH-K MATERIAL DEPOSITION”.

### FIELD OF THE INVENTION

The present invention relates generally to high-K gate stack and capacitor stack fabrication processes in micro-integrated circuit fabrication and more particularly, to a method of treating the base (underlying) oxide or Si substrate to improve the deposition of overlying high-K materials.

### BACKGROUND OF THE INVENTION

Fabrication of a metal-oxide-semiconductor (MOS) integrated circuit involves numerous processing steps. A gate oxide is typically formed from thermally grown silicon dioxide over silicon or polysilicon which is doped with either n-type or p-type dopants. For each MOS field effect transistor (MOSFET) being formed, a gate electrode is formed over the gate dielectric, and dopant impurities are then introduced into the semiconductor substrate to form source and drain regions. Many modern day semiconductor microelectronic fabrication processes form features having less than 0.25 micron critical dimensions, for example more recent devices include features sizes of less than 0.13 microns. As design rules decrease, the size of a resulting transistor as well as transistor features also decrease. Fabrication of smaller transistors allows more transistors to be placed on a single monolithic substrate, thereby allowing relatively large circuit systems to be incorporated on a single die area.

In the formation of gate electrodes and capacitor devices, a trend in semiconductor microelectronic device fabrication, is increasingly is to use high-K (high dielectric constant materials) as the gate dielectric stack and as the capacitor stack. Because of high direct tunneling currents, SiO₂ films thinner than about 20 Angstroms cannot be reliably used as a gate dielectric in CMOS devices. There are currently intense efforts to replace traditional SiO₂ gate dielectric films with high-K dielectric materials. A high dielectric constant gate dielectric allows a thicker gate dielectric to be formed which dramatically reduces tunneling current and consequently gate leakage current, thereby overcoming a severe limitation in the use of SiO₂ as the gate dielectric. While silicon dioxide (SiO₂) has a dielectric constant of approximately 4, other candidate high-K dielectrics have significantly higher dielectric constant values of, for example, 20 or more. Using a high-K material for a gate dielectric allows a high capacitance to be achieved even with a relatively thick dielectric. Typical candidate high-K dielectric gate oxide materials have high dielectric constant in the range of about 20 to 40.

There have been, however, difficulties in forming high-k gate dielectrics to achieve acceptable processing integration between the high-K gate dielectric and an underlying base oxide layer or Si substrate. For example, in the formation of high-K dielectric stacks, Atomic layer chemical vapor deposition (ALCVD) is commonly used to form the high-K materials layers over a silicon substrate having a base oxide formed over the substrate. Since a base oxide can readily form over the silicon from atmospheric exposure and produces a rough deposition surface unsuitable for epitaxy or ALCVD, a silicon wafer cleaning process is typically undertaken to first form a chemically produced oxide surface on the silicon for forming overlying ALCVD layers. For example, the uniformity of the high-K/semiconductor wafer interface is critical, since the excessive formation of surface defects in the form of, for example, dislocations, provides trapping sites or charge accumulation areas which interfere with acceptable gate dielectric performance. However, neither the formation of chemically produced oxides on the silicon wafer surface nor the growth of thermal oxides provides a surface quality that is sufficiently free of surface defects, especially for design rules approaching 0.13 microns and below. For example, electrical performance properties of the high-K dielectric stack may suffer due the reduced quality of the high-K/SiO₂/silicon interface.

In addition, surface defects at the SiO₂/silicon interface may provide nucleation sites for crystallization of amorphous high-K material leading to undesirable crystallization. For example, forming of a crystalline structure under normal preparation conditions leads to a roughened film surface. Surface roughness causes non-uniform electrical fields in the channel region adjacent the dielectric film. Such films are not suitable for the gate dielectrics of MOSFET devices, especially in smaller device technologies approaching 0.13 microns and below.

Proposed solutions to improve processing condition for forming high-k gate dielectrics with acceptable electrical properties, such as capacitance and leakage current, have included efforts to improve the thermal stability of the high-k dielectric films thereby avoiding film crystallization, or to provide processes whereby lower process temperatures (lower thermal budgets) are achieved, which have met with limited success.

Therefore it would be advantageous to develop an improved method for forming high-K dielectric stacks having improved surface interfaces to improve an electrical performance of the high-K dielectric stack.

It is therefore an object of the invention to provide an improved method for forming high-K dielectric stacks having improved surface interfaces to improve an electrical performance of the high-K dielectric stack, in addition to overcoming other shortcomings and deficiencies of the prior art.

### SUMMARY OF THE INVENTION

To achieve the foregoing and other objects, and in accordance with the purposes of the present invention, as embodied and broadly described herein, the present invention provides a method for forming a high-K material layer in a semiconductor device fabrication process.

In a first embodiment, the method includes providing a silicon semiconductor substrate; thermally growing an interfacial oxide layer comprising silicon dioxide over the silicon substrate; treating the interfacial oxide layer surface with an aqueous ammonium hydroxide (NH₄OH) containing solution; and, depositing a high-K material layer over the interfacial oxide layer.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIG. 1 is an exemplary CMOS device including a high-K dielectric stack according to an embodiment of the invention.

FIGS. 2A-2B are cross sectional views of a portion of an exemplary multi-layer high-K dielectric layer stack at stages in manufacture according to an embodiment of the present invention.

FIGS. 3A-3B are graphical representations of Capacitance-ge Voltage (CV) data taken of a process wafer including semiconductor devices produced with processing methods according to embodiments of the present invention contrasted with processing method excluding embodiments of the present invention.

FIGS. 4A-4B are graphical representations of Capacitance-Voltage (CV) data taken of a process wafer including semiconductor devices produced with processing methods according to embodiments of the present invention contrasted with processing method excluding embodiments of the present invention.

FIG. 5 is a process flow diagram including several embodiments of the present invention.

### DETAILED DESCRIPTION OF THE PREFERRED EMBODIMENTS

Although the method of the present invention is explained with reference to the formation of an exemplary high-K gate dielectric stack, it will be appreciated that the method of the present invention may be used for the formation of high-K gate dielectrics for MOSFET devices as well as capacitor stacks in a micro-integrated circuit manufacturing process.

Although the method of the present invention is explained with reference to the use of exemplary high-k gate dielectrics it will be appreciated that the method of the present invention may be adapted for the use of any high-k material in the formation of a gate dielectric. By the term high-k dielectric is meant a material that has a dielectric constant of greater than about 10. The term “substrate” is defined to mean any semiconductor substrate material including conventional silicon semiconductor wafers.

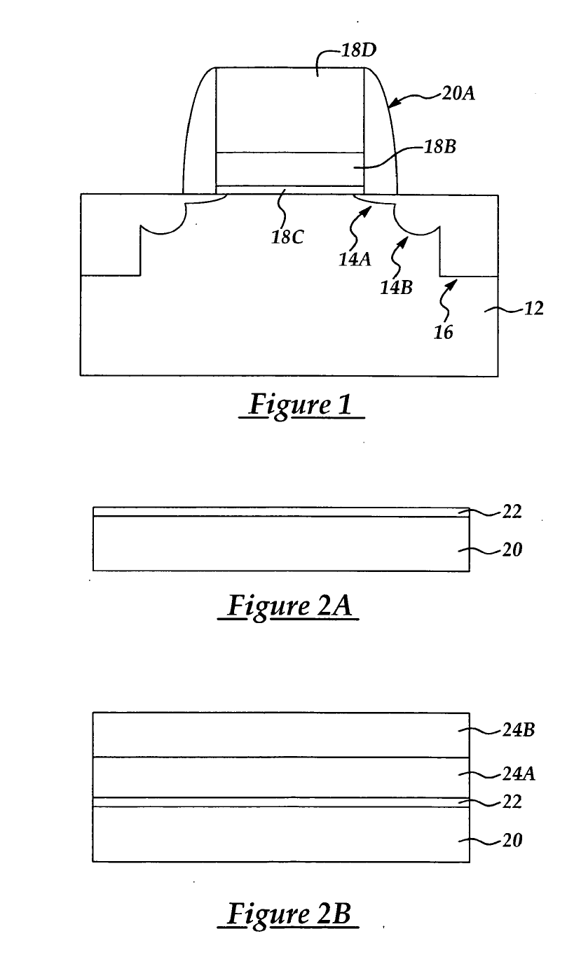

Referring to FIG. 1A is shown a cross sectional schematic of an exemplary CMOS transistor having a high-k dielectric gate structure including a gate stack according to an embodiment of the present invention. Referring to FIG. 1, is shown semiconductor substrate 12, for example a silicon substrate including lightly doped regions e.g., 14A, source/drain regions, e.g., 14B and shallow trench isolation regions, e.g., 16 formed in the silicon substrate by conventional methods known in the art. The regions 14A and 14B are typically formed following the formation of the gate structure including the gate dielectric region 18B formed of multiple layers including for example, an interfacial silicon dioxide layer 18C, and gate electrode portion 18D, for example polysilicon. The gate structure is typically formed by conventional photolithographic patterning and anisotropic etching steps following polysilicon deposition. Following gate structure formation a first ion implantation process is carried out to form LDD regions e.g., 14A in the silicon substrate. Sidewall spacers e.g., 20A, are formed including for example at least one of silicon oxide (e.g., SiO₂), silicon oxynitride (e.g., SiON), and silicon nitride (e.g., SiN) including multiple layered spacers by methods known in the art including conventional deposition and etchback processes. A second ion implantation process is then carried out to form the source/drain regions e.g., 14B in a self aligned ion implantation process where the sidewall spacers e.g., 20A act as an implantation mask to form N type or P type doping regions depending on whether a PMOS or NMOS type device is desired.

Referring to FIG. 2A is shown an expanded cross sectional side view of a portion of the gate stack region, e.g., 18C and 18B in FIG. 1 at stages in manufacture. In an exemplary embodiment, is shown a semiconductor substrate 20, preferably single crystalline silicon having (111) or (100) orientation.

The substrate may also be composed of a layered semiconductor such as Si/SiGe or Si/SiO₂/Si. The substrate may be of the n or p-type and preferably includes several active regions, for example N or P doped regions forming active charge carrying regions forming a portion of a MOFSET device.

In an exemplary embodiment of the present invention, in a first step the silicon substrate 20 is cleaned prior to formation of an overlying thermally grown SiO₂ interfacial layer 22, also referred to as a base oxide layer. In one embodiment, preferably the silicon substrate is cleaned using standard cleaning 1 (SC-1) and/or standard cleaning-2 (SC-2) solutions, which may be individually or sequentially used cleaning solutions including mixtures of NH₄OH—H₂O₂—H₂O, and HCl—H₂O₂—H₂O, respectively.

Still referring to FIG. 2A, in one embodiment of the invention, following the silicon substrate cleaning process, an interfacial oxide layer 22 is provided over the silicon substrate 20, preferably formed to a thickness of about 5 Angstroms to about 30 Angstroms over the silicon substrate and preferably formed by a thermal oxidation method including furnace and rapid thermal oxidation (RTO) methods at temperatures from about 800° C. to about 1100° C. Thermal oxide growth methods are a preferred embodiment according to the present invention due to a superior quality Si/SiO₂ interface. In one embodiment, an In-Situ-Steam-Generated (ISSG) method is used to grow the thermal oxide, for example growing the interfacial oxide layer at a temperature of from about 700° C. to about 850° C., followed by an oxide anneal in nitrogen ambient at about 900° C. to about 1050° C.

Following the formation of the interfacial oxide layer 22, the interfacial oxide layer surface is exposed to a surface treatment to enhance a subsequent atomic layer CVD (ALCVD) deposition of high-K material to form a high-K dielectric/interfacial oxide layer interface with reduced surface defects. The surface treatment is preferably selected from an aqueous solution treatment with an ammonium hydroxide (NH₄OH) containing solution, an annealing treatment in an ambient including at least one of NO gas and NH₃ gas, and a plasma assisted surface treatment including at least one of NH₃ gas and N₂ gas as a plasma source gas. It will be appreciated that more than one surface treatment may be undertaken, for example, an aqueous solution treatment following an annealing or plasma assisted treatment, an annealing treatment following a plasma assisted treatment, or a plasma assisted treatment following either an aqueous treatment or annealing treatment. In a preferred embodiment, one of a plasma assisted treatment and an annealing treatment is undertaken according to preferred embodiments prior to an aqueous solution treatment, which precedes ALCVD deposition of a high-K material.

For example, it has been found that a surface treatment according to preferred embodiments preceding deposition of a high-K material, significantly improves the quality of the deposited high-K dielectric as evidenced by subsequent electrical properties such as capacitance-Voltage (CV) curves, and flatband Voltage (V_{fb}) derived there from. Preferred High-K dielectrics include binary metal oxides such as tantalum oxides (e.g., Ta₂O₅), titanium oxides, (e.g., TiO₂), hafnium oxides (e.g., HfO₂), yttrium oxides (e.g., Y₂O₃), lanthanum oxides (e.g., La₂O₅), zirconium oxides (e.g., ZrO₂), and silicates and aluminates thereof. However, it will be appreciated that other materials having a dielectric constant greater than about 10, more preferably about 20 may be suitably used.

In one embodiment, the aqueous treatment is carried out by contacting the interfacial oxide layer surface with an aqueous ammonium hydroxide (NH₄OH) containing solution. Preferably the aqueous ammonium hydroxide (NH₄OH) containing solution has a concentration of NH₄OH ranging from about 0.5% by volume to about 33% by volume ammonium hydroxide. More preferably, the aqueous NH₄OH containing solution has a concentration of NH₄OH from about 2% by volume to about 33% by volume ammonium hydroxide. Most preferably, concentration of NH₄OH is from about 2% by volume to about 10% by volume. Other additives may optionally be included in the surface treatment solution including H₂O₂ and HCl to assist in simultaneous cleaning of the interfacial oxide layer surface. More preferably, the interfacial oxide layer is first cleaned with standard cleaning solutions followed by contacting the interfacial layer surface with a basic aqueous ammonium hydroxide solution according to preferred embodiments. For example in one embodiment, the process wafer including the interfacial oxide layer surface is first dipped into a cleaning solution including at least one of an SC1 (standard cleaning solution 1) including an H₂O₂/NH₄OH/H₂O solution and SC2 including HCl/NH₄OH/H₂O solution, followed by dipping the process wafer in the aqueous NH₄OH surface treatment solution according to preferred embodiments. The surface treatment in the aqueous NH₄OH containing solution is preferably carried out at a temperature of from about 23° C. to about 80° C., for a period of from about 30 seconds to about 90 seconds, a shorter time period required for a higher temperature solution.

It will be appreciated that methods other than dipping may be used for contacting the interfacial oxide layer surface with the NH₄OH surface treatment solution including spin/spray techniques. The aqueous NH₄OH surface treatment solution may be provided in dipping baths including agitating means such as megasonic or pressurized gas for producing bubbles.

In another embodiment, the interfacial oxide layer is subjected to an annealing treatment (annealing nitridation) in the presence of at least one of nitric oxide (NO) and ammonia (NH₃). The annealing treatment may take place in a wet oxidation furnace for example, following a wet thermal oxide growth process for example, an In-Situ-Steam-Generated (ISSG) method at a temperature of from about 700° C. to about 850° C., followed by an oxide anneal in nitrogen ambient at about 900° C. to about 1050° C. The annealing treatment is preferably carried out in an NO and/or NH₃ containing ambient anneal at about 700° C. to about 900° C., for example including from about 1 Vol % to about 50 Vol % of NO and/or NH₃ with the remaining portion made up of N₂, for a period of from about 5 minutes to about 30 minutes. Following the annealing treatment, the process wafer may additionally be cooled in the presence of the NO and/or NH₃ containing ambient. In one embodiment, preferably a mixture of NO/NH₃ is used in the annealing treatment having a ratio of NH₃ to NO of from about 1 to 1 to about 3 to 1. It will be appreciated that one or more of alternative surface treatments according to preferred embodiments may precede or follow the NO annealing treatment. For example, following the annealing treatment, the aqueous NH₄OH surface treatment is preferably carried out.

In another embodiment, the interfacial layer is subjected to a plasma assisted surface treatment (plasma nitridation) including at least one of NH₃ gas and N₂ gas as a plasma source gas. The NH₃ gas and N₂ gas may be use separately or mixtures may be formed, for example, having about a volumetric ratio of NH₃ to N₂ of about 1 to 1 to about 3 to 1. In addition, an inert gas such as He and Ar may be included in the mixture to assist in the formation of the plasma. The plasma is preferably formed as a high density plasma. For example, the plasma may be generated by conventional plasma sources such as helicon; helical-resonator; electron-cyclotron resonance; or inductively coupled. For example, using an ICP source, an RF power of about 100 Watts to about 500 Watts is suitably used. An RF or DC bias may be optionally applied to the process wafer surface. Preferably, the plasma assisted surface treatment is carried out at pressures on of about 1 to about 50 mtorr, and temperatures of about 0° C. to about 400° C., for a period of about 10 seconds to about 60 seconds.

It will be appreciated that the plasma assisted surface treatment may be carried out preceding or following other surface treatments according to preferred embodiments, for example following the annealing treatment. In addition, the aqueous NH₄OH surface treatment is preferably carried out following the plasma assisted surface treatment, prior to deposition of an overlying high-K material layer. In an alternative preferred embodiment, the plasma assisted surface treatment is carried out in-situ prior to deposition of the high-K material, for example a hafnium oxide (e.g., HFO₂) layer. The plasma assisted surface treatment, if carried out following the aqueous NH₄OH containing solution treatment is preferably is carried out at temperatures less than about 300° C. to minimize surface dihydroxylation. In one embodiment, an annealing or plasma nitridation process is carried out according to preferred embodiments, followed by the aqueous NH₄OH surface treatment, and followed by a 2d plasma nitridation treatment in-situ prior to high-K layer deposition according to preferred embodiments at a temperature less than about 300° C.

Referring to FIG. 2B, following growth of the interfacial oxide layer 22, and one or more interfacial oxide surface treatments according to preferred embodiments, one or more high-k dielectric layers e.g., 24A, 24B are deposited over the interfacial oxide layer to form a dielectric layer stack. The high-k dielectric materials used to form the dielectric layer stack preferably have a dielectric constant of greater than about 10, more preferably greater than about 20. Most preferably, the high-K dielectric layer stack includes a lowermost layer formed of hafnium oxide (e.g., HfO₂). The lowermost high-k dielectric layer e.g., 24A is preferably formed by atomic layer chemical vapor deposition (ALCVD). The high-k dielectric layers forming the dielectric layer stack e.g., 24A, 24B are preferably formed having a total thickness of between about 20 Angstroms to about 100 Angstroms.

The ALCVD deposition process preferably takes place with the wafer substrate heated from about 300° C. to about 400° C. An ALCVD process is preferred since it gives interface and film qualities where molecular layers are sequentially deposited including a molecular layer of metal precursor, for example a metal-organic precursor, followed by controlled dissociation and oxidation of the metal-organic molecular layer to form a portion of the high-k dielectric layer, the process being sequentially repeated to complete the formation of the high-K dielectric layer. It will be appreciated that other processes such as MOCVD or PECVD using metal-organic precursors may be used as well, but are less preferred methods of deposition due to lower quality electrical properties.

Following deposition of the high-K dielectric layer e.g., 24A, or a stack of high-K dielectric layers e.g., 24A, 24B, the high-K dielectric layers are preferably annealed in a hydrogen containing atmosphere at a temperature from about 600° C. to about 800° C. and preferably followed by an anneal in an oxygen containing atmosphere at temperatures from about 600° C. to about 900° C. to improve the high-K oxide quality and dielectric properties.

Following formation of a high-K dielectric layer stack to form a portion of a gate structure or capacitor stack, conventional processes are completed to form a MOFSET device structure including, for example, polysilicon layer deposition and etching processes to form e.g., a gate structure.

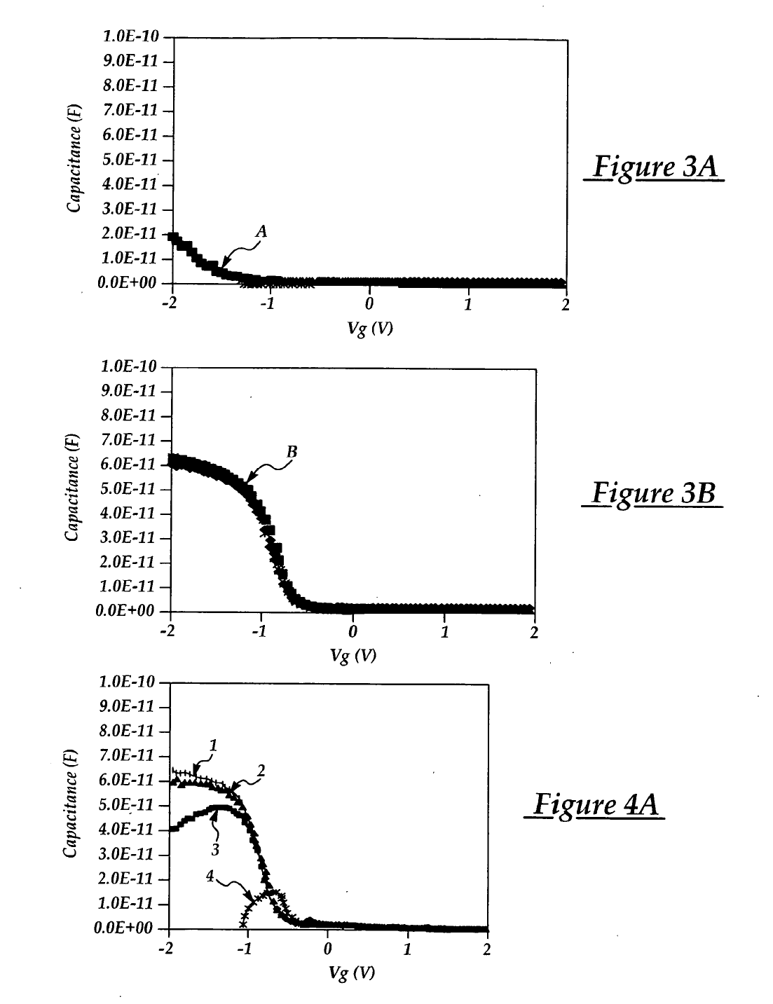

Referring to FIGS. 3A-3B are shown representative Capacitance-Voltage (CV) data curves obtained by conventional methods showing capacitance on the vertical axis and applied gate voltage on the horizontal axis. FIG. 3A shows the CV curve, A, representing overlapping data from separate CV measurements over different areas of the wafer surface where measure structures included the thermal oxide (interfacial oxide) layer formed by an ISSG method and overlying high K dielectric layer (HFO₂) formed by an ALCVD method without surface, including the aqueous NH₄OH containing surface treatment. FIG. 3B shows the CV curve, B, also representing several overlapping data from measurements over different areas of the wafer surface obtained from the same structure but including an aqueous NH₄OH containing surface treatment having about 2% by volume NH₄OH according to preferred embodiments of the present invention. Although higher concentrations of NH₄OH in the surface treatment solution gave about comparable results, the best results were obtained for concentrations of NH₄OH between about 1% by volume to about 10% by volume.

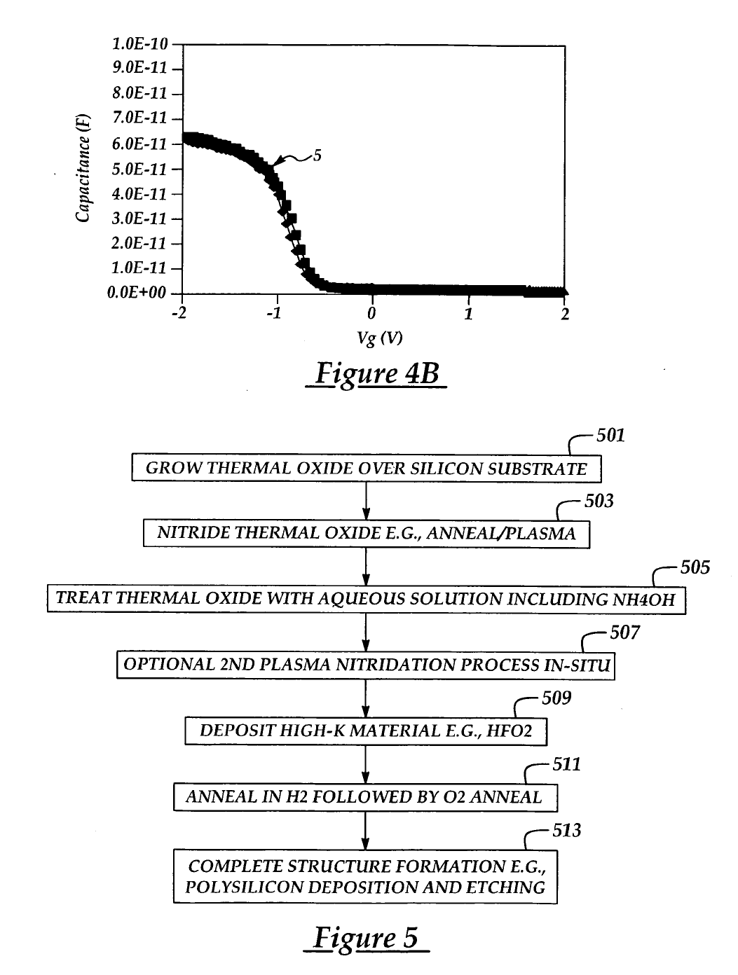

Referring to FIGS. 4A-4B, are shown representative CV curves obtained in the same manner as discussed with respect to FIGS. 3A and 3B, where FIG. 4A represents CV curves, e.g., 1, 2, 3, 4 taken over predetermined areas of the process wafer surface including structures including the interfacial oxide grown by an RPO method and formation of an overlying HFO₂ high-K dielectric layer by an ALCVD method including an aqueous NH₄OH containing surface treatment but without an NO surface annealing treatment. FIG. 3B, by contrast shows a single CV curve, 5, where the data taken over the same predetermined areas of the process wafer surface are overlapping and indistinguishable. In FIG. 3B, the interfacial oxide layer was subjected to both an NO annealing treatment followed by an aqueous NH₄OH containing surface treatment. Thus, good results have been found to be realized when one of an annealing treatment or plasma assisted surface treatment according to preferred embodiments is followed by an aqueous NH₄OH containing surface treatment.

While not being bound by the following explanation, it is believed that the annealing treatments and plasma assisted plasma treatments incorporate nitrogen into the thermal oxide surface which typically leaves areas on the wafer surface, either unhydroxylated or otherwise rendered hydrophobic and not conducive to ALCVD deposition of high-K binary metal oxides. The annealing and plasma assisted treatments according to preferred embodiments, together with the aqueous NH₄OH containing surface treatment produces improved CV results, believed to be due to providing a hydrophilic surface conducive to subsequent ALCVD deposition. An added benefit of the annealing treatments and plasma assisted plasma treatments according to preferred embodiments is the incorporation an amount of nitrogen into the interfacial oxide layer, for example from about 0.5 to about 4 wt % which has the effect of increasing the dielectric constant of the interfacial oxide layer, thereby allowing a thinner high-K dielectric layer stack to be formed, as well as inhibiting growth of the interracial oxide layer during subsequent annealing processes.

Referring to FIG. 5 is a process flow diagram including several embodiments of the present invention. In a first process 501, a thermal oxide is grown over a silicon substrate. In process 503, the thermal oxide is nitrided according to at least one of an annealing and plasma assisted surface treatment. In process 505, the interfacial oxide layer is contacted with an aqueous solution of NH₄OH according to preferred embodiments. In process 507, an optional 2d plasma nitridation process is carried out in-situ prior to high-K dielectric layer deposition. In process 509, a high-K dielectric layer stack, for example including a lowermost layer of HFO₂, is formed by ALCVD. In process 511, following formation of a high-K dielectric layer stack to form a portion of a gate structure or capacitor stack, a hydrogen annealing step followed by an oxygen annealing step is carried out. In process 513, conventional processes are completed a MOFSET device structure including, for example, polysilicon layer deposition and etching processes to form e.g., a gate structure.

While the embodiments illustrated in the Figures and described above are presently preferred, it should be understood that these embodiments are offered by way of example only. The invention is not limited to a particular embodiment, but extends to various modifications, combinations, and permutations as will occur to the ordinarily skilled artisan that nevertheless fall within the scope of the appended claims.

What is claimed:

1. A method for forming a high-K material layer in a semiconductor device fabrication process comprising the steps of:
providing a substrate;
forming an interfacial oxide layer over said substrate;
treating said interfacial oxide layer with an aqueous ammonium hydroxide (NH₄OH) containing solution; and,
depositing at least one high-K material layer over said substrate.

2. The method of claim 1, wherein the ammonium hydroxide (NH₄OH) containing solution further comprises at least one of H₂O₂ and HCI.

3. The method of claim 1, wherein the interfacial oxide layer is grown to a thickness of about 5 Angstroms to about 100 Angstroms.

4. The method of claim 1, wherein the step of depositing at least one high-K material layer comprises an atomic layer chemical vapor deposition (ALCVD) method.

5. The method of claim 1, further comprising a step between the formation of said interfacial oxide layer and treatment of said interfacial oxide layer with said aqueous-ammonium hydroxide containing solution, the step comprising:
dipping said interfacial oxide layer into a cleaning solution including at least one of a first solution, including H₂O₂/NH₄OH/H₂O solution, and a second solution, including HCl/NH₄OH/H₂O.

6. The method of claim 1, further comprising a step prior to the formation of said interfacial oxide layer, the step comprising:
cleaning said substrate using at least one of a first standard cleaning solution and a second cleaning solution, wherein said first cleaning solution includes a mixture of NH₄OH—H₂O₂—H₂O, and said second cleaning solution includes a mixture of HCl—H₂O₂—H₂O.

7. The method of claim 1, wherein treatment of said interfacial oxide layer with said aqueous ammonium hydroxide containing solution is carried out at a temperature from about 23° C. to about 80° C., for a period of from about 30 seconds to about 90 seconds.

8. The method of claim 1, wherein treatment of said interfacial oxide layer with said aqueous-ammonium hydroxide containing solution is performed by a techniques selected from a group consisting of dipping said interfacial oxide layer into said interfacial oxide layer into said aqueous ammonium hydroxide containing solution, a spin techniques with said aqueous ammonium hydroxide containing solution, and a spray techniques with said aqueous ammonium hydroxide containing solution.
